(19) United States
(12) Patent Application Publication
(10) Pub. No.: US 2009/0219032 A1
(43) Pub. Date: Sep. 3, 2009

(54) SYSTEM AND METHOD FOR DETERMINING CIRCUIT FUNCTIONALITY UNDER VARYING EXTERNAL OPERATING CONDITIONS

(75) Inventors: Alessandro Minzoni, Xi'an (CN); Bin Wang, Xi'an (CN)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/039,333

(22) Filed: Feb. 28, 2008

(51) Int. Cl. G01R 31/08

(52) U.S. Cl. 324/527

(57) ABSTRACT

A system and method for determining circuit functionality under varying external operating conditions. One embodiment provides a circuit for a given input signal. Internal signals are generated at internal nodes for the given input signal and the next set of external operating conditions. The internal signals are compared with internal reference signals to determine whether the integrated circuit is functional under the next set of external operating conditions. If the circuit is found functional under the next set of external operating conditions, then the internal reference signals are set equal to the internal signals, the initial set of external operating conditions are set equal to the next set of external operating conditions, and the above described method is repeated.

### BACKGROUND

One or more embodiments relate to determining circuit functionality under varying external operating conditions based upon an analysis of internal circuit signals. One embodiment relates determining whether a circuit is internally consistent under various external operating conditions based upon timing comparisons of signals generated at internal circuit nodes.

Conventional shmoo plots are typically generated by a chip testing device. Conventional shmoo plots are based upon comparing an actual output chip signal with a (theoretically) expected chip output signal for a given input signal as external operating conditions are varied. External operating conditions may include an input signal frequency or a clock-duty cycle, for example.

FIG. 1 is an illustration of a conventionally-generated shmoo plot, in which an external voltage (V) and an external temperature (T) are varied. As illustrated in FIG. 1, the shmoo plot indicates whether the chip “passes” (as indicated by an asterisk) or “fails” (as indicated by an X) for each variation of external voltage and temperature. Whether the chip “passes” or “fails” is typically based upon comparing the actual chip-generated output signal with the theoretically expected chip output signal for a given input signal. For example, a comparison of the waveform of the actual chip output signal to the waveform of the expected chip output signal may be made, or other signal indicia may be used in comparing the two output signals. If the two output signals are determined to be dissimilar based upon waveforms or other signal indicia, then the chip fails to operate properly for that given set of external operating conditions.

In order to generate a conventional shmoo plot, a chip testing device typically applies appropriate bias voltages and a chip input signal. The chip testing device applies the input signal to the chip as the external operating conditions are varied over some predefined range of operating conditions under which the chip is to tested. The chip testing device senses the chip output for the different values of the external operating conditions. The chip testing device may then compare the chip output signal with the theoretically expected output signal, and determine, based upon some predefined set of signal indicia, whether the chip passes or fails to perform within acceptable design specifications. In this manner, the chip testing device generates a conventional shmoo plot.

Conventional shmoo plots generated by chip testing devices result from a comparison of actual chip output signals with expected output signals. However, although the chip may “pass” based upon a comparison of output signals, the chip may not be operating properly internally. FIG. 2 is an illustration of a comparison of expected and actual output of a chip having internal signal inconsistencies in generating a “pass” on a conventional shmoo plot. As illustrated, curve 202 is a timing or clocking signal and curve 204 is a collective representation of five theoretically-predicted expected output data. For example, the digits “01011” represent the five output data expected at five different output pads or ports of the chip during a first clocking cycle, where for example, pad one has an expected output of 0, pad two has an expected output of 1, pad three has an expected output of 0, pad four has an expected output of 1 and pad five has an expected output of 1. During the second clocking cycle, the digits “01100” represent the expected output data at the five different output pads of the chip during a second clocking cycle, where for example, pad one has an expected output of 0, pad two has an expected output of 1, pad three has an expected output of 1, pad four has an expected output of 0 and pad five has an expected output of 0.

Curve 206 is a collective representation of five theoretically-predicted expected internal signals. The digits “11001” represent five expected internal signals at five different internal nodes of the chip during the first clocking cycle, and the digits “00111” represent five expected internal signals at the same five internal nodes of the chip during the second clocking cycle.

Curve 208 is a collective representation of five actual output data measured by the chip testing device at the five different output pads or ports of the chip. As seen by comparing curves 204 and 208, the five actual output data measured by the chip testing device are identical to the five predicted or theoretically expected output data during both the first clocking cycle and the second clocking cycle. Based upon the output data, the conventional chip testing device will indicate that the chip has “passed” for the given external operating condition.

However, even though a conventional shmoo plot generated by the chip testing device indicates that the chip has “passed” and is considered to be functional for the given external operating condition, a comparison of curve 206 (illustrating the expected internal signals at five internal nodes during the two clocking cycles) with curve 210 (illustrating the actual internal signals at the same five internal nodes during the two clocking cycles) indicates that there are inconsistencies in internal chip signals. That is, one or more internal states of the chip, as manifested by glitches or a flipping of states at internal chip nodes, may not be stable. As illustrated, curve 210 depicts an unstable internal state represented by digits “11111.” More specifically, the two internal nodes with internal state values of “0” during the first clocking cycle have flipped to internal state values of “1,” thereby initiating the unstable transitory period of curve 214 in which all five internal nodes have internal state values of “1.” A conventional shmoo plot may indicate that the chip has “passed” when in reality the chip has internal signals that are unstable and inconsistent.

Shmoo plots based upon internal signals are problematic to run, given that internal signals are difficult to measure and/or generate. It would be advantageous for chip design engineers to have a tool that could detect internal inconsistencies with a particular chip design before the chip has been fabricated.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a illustration of a conventionally-generated shmoo plot, in which an external voltage and an external temperature are varied.

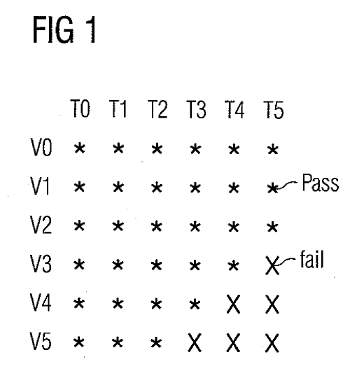

FIG. 2 is an illustration of a comparison of expected and actual output of a chip having internal signal inconsistencies in generating a “pass” on a conventional shmoo plot.

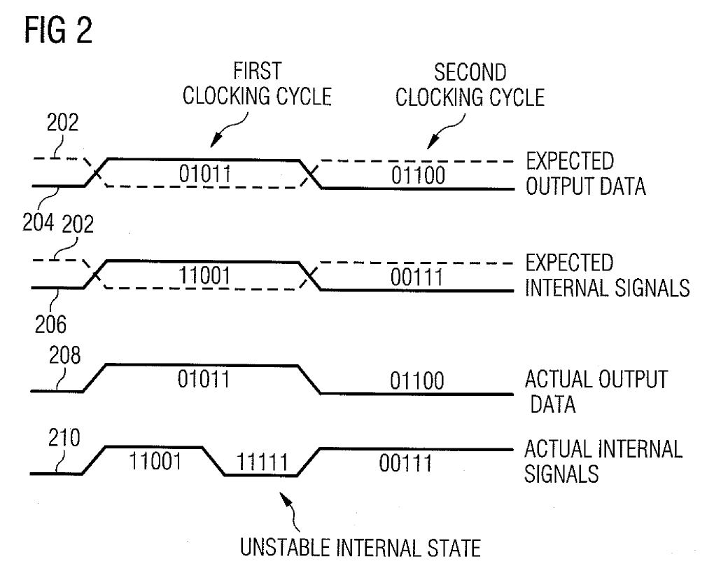

FIG. 3 is an illustration of collective internal states of a properly functioning circuit, according to one embodiment.

FIG. 4 is an illustration of collective internal states of an improperly functioning circuit, according to one embodiment.

FIG. 5 is an illustration of an internal state representing an improperly functioning chip, according to one embodiment.

FIG. 6 is flowchart of a method for testing internal chip signals to determine chip functionality, according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

Various embodiments provide for a system and method for testing internal data generated by a circuit and verifying that each block of the circuit functions within appropriate design specifications. In one embodiment, the method compares a timing of internal signals of a circuit for different external operating conditions to determine whether the circuit is operating in an internally consistent manner. The method may detect internal signal inconsistencies even when the circuit appears to be operating properly, based upon its consistent output signals. The circuit may be an integrated semiconductor circuit. The system and method expands the scope of analyzing chip functionality on which conventionally-generated shmoo plots are based.

One embodiment provides a method is provided for determining functionality of a circuit for a given input signal and slowly varying external boundary conditions. The circuit has one or more internal nodes at which one or more internal signals are generated and/or measured. In one embodiment, one or more internal reference signals are generated and/or determined for a given input signal and an initial set of one or more external boundary conditions. In one embodiment, a set of external boundary conditions may include temperature and an externally applied voltage. However, any number of externally-applied operating conditions may include the set of external boundary conditions.

According to one embodiment, at least one external operating condition of the initial set of external operating conditions is incremented to produce a next set of external operating conditions. One or more internal signals are generated at the one or more internal nodes for the given input signal and the next set of external operating conditions. Subsequently, the one or more internal signals are compared with the one or more internal reference signals to determine whether the integrated circuit is functional under the next set of external operating conditions.

In another embodiment, the comparison of the internal signals generated under the next set of external operating conditions with the internal reference signals produces timing differences between the internal reference signals and the internal signals. In one embodiment, a timing difference of a specific internal signal is a timing comparison between the specific internal signal and the internal reference signal measured at the same internal node. In yet another embodiment, a timing difference of an internal signal at a certain node is based upon comparing a time at which the internal signal changes a state with a time at which the internal reference signal changes a state.

In another embodiment, if the circuit is found functional under the next set of external operating conditions, then the one or more internal reference signals are set equal to the one or more internal signals. Then, at least one external operating condition of the next set of external operating conditions is incrementally changed to produce a further next set of one or more external operating conditions. One or more internal signals at the one or more internal nodes are generated for the given input signal and the further next set of external operating conditions. Subsequently, the newly generated internal signals are compared with the last set of internal signals generated under the next set of external operating conditions to determine whether the integrated circuit is functional under the further next set of external operating conditions. In a further embodiment, if the integrated circuit is found functional under the further next set of external operating conditions, the next set of external operating conditions are set equal to the further next set of external operating conditions, and the above steps of setting, incrementing, generating and comparing are repeated.

In another embodiment, an electronic-readable medium has embodied thereon a program being executable by a machine for determining functionality of a circuit for a given input signal and slowly varying external boundary conditions. The program may be executable to perform any combination of the embodiments as described above.

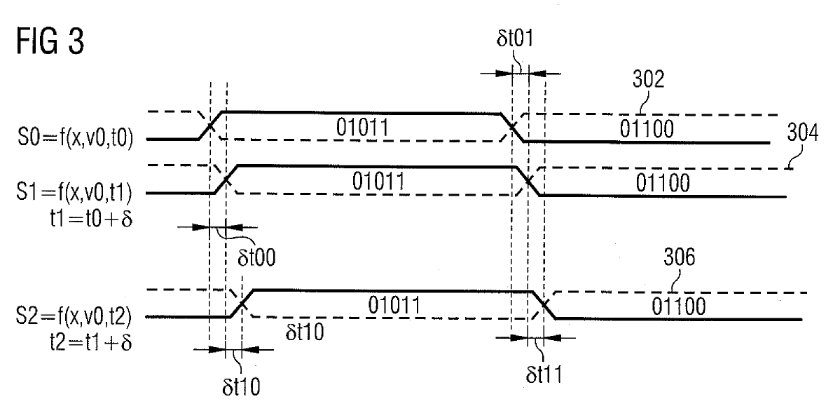

FIG. 3 is an exemplary illustration of collective internal states of a properly functioning circuit, according to one embodiment. As illustrated, the collective internal states of the circuit are represented by a plurality of internal signals measured (or generated) at a plurality of internal circuit nodes as one or more external operating conditions are slowly varied. In one embodiment, the circuit is an integrated circuit (i.e. a chip).

The curve S0 represents collective internal states of the circuit (or chip) for a given temperature t0, a given external voltage v0, a given circuit input signal x, and clocked by a given clocking signal 302. In the exemplary embodiment as illustrated, a first collective internal state during a first clocking cycle is represented by five signals “0,” “1,” “0,” “1,” “1” measured and/or generated at five internal circuit nodes, respectively. Some of the states of the five internal signals are changed during a second clocking cycle. This second set of internal states of the five internal signals represents a second collective internal state of the circuit. As illustrated, the second collective internal state is represented by five internal signals “0,” “1,” “1,” “0,” “0” measured and/or generated at the same five internal circuit nodes, respectively.

A reference curve corresponds to a circuit which is functioning properly according to its design specifications, based upon a comparison of internal signals and optionally on a comparison of output signals (predicted versus actual). In one embodiment, and for purposes of illustration, curve S0 is an internal reference curve representing a properly functioning circuit (both with respect to internal signals and signal output) for a given set of initial external boundary conditions (e.g., a given temperature t0 and a given external voltage v0) to which a next generated curve representing collective internal states of the circuit may be compared.

The curve S1 represents collective internal states of the circuit for a given temperature t1, the given external voltage v0, the given chip input signal x, and clocked by a given clocking signal 304. Curve S1 is generated with an applied external temperature t1 that is incrementally changed from the temperature under which curve S0 is generated. As illustrated, t1=t0+δ, where δ represents the incremental change in temperature. Curve S1 has a first collective internal state represented by the states “0.” “1,” “0.” “1,” “1” measured and/or generated during a first clock cycle and a second collective internal state represented by the states “0.” “1,” “1,” “0.” “0” measured and/or generated during a second clock cycle. The onset of the first collective internal state of curve S1 is delayed in time from the onset of the first collective internal state of curve S0 by a time increment δt00. Similarly, the onset of the second collective internal state of curve S1 is delayed in time from the onset of the second collective internal state of curve S0 by a time increment δt01. The time increments δt00 and δt01 may or may not have the same value.

Similarly, the curve S2 represents collective internal states of the circuit for a given temperature t2, the given external voltage v0, the given chip input signal x, and clocked by a given clocking signal 306. Curve S2 is generated with an applied external temperature t2 that is incrementally changed from the temperature under which curve S1 is generated. As illustrated, t2=t1+δ, where δ represents the incremental change. Curve S2 has a first collective internal state represented by the states “0.” “1,” “0.” “1,” “1” measured and/or generated during a first clock cycle and a second collective internal state represented by the states “0.” “1,” “1,” “0.” “0” measured and/or generated during a second clock cycle. The onset of the first collective internal state of curve S2 is delayed in time from the onset of the first collective internal state of curve S1 by a time increment δt10. Similarly, the onset of the second collective internal state of curve S2 is delayed in time from the onset of the second collective internal state of curve S1 by a time increment δt11. δt11 and δt10 may or may not have the same values. The time increments may also be referred to as timing delays and timing differences.

It is known that a nonlinear system may be modeled to give linear responses to applied perturbations if the applied perturbations are incrementally small. Thus, if the system including the circuit is internally functioning properly and has internally consistent signals, then any incremental change in an external boundary condition will generate a similar incremental change in the timing of the internal signals (represented collectively in FIG. 3 by the collective internal states of the circuit). However, if one or more internal states of the circuit, represented by any of the measured and/or generated signals at the internal nodes of the circuit, is unstable, then the timing of the internal signals will no longer be linear.

In one embodiment, the timing differences are compared to a predefined timing difference threshold δtth to determine whether the circuit is internally functioning properly. For the purposes of illustration, assume that δt00 and δt01 are less than the predefined timing delay threshold δtth. Consequently, given that the internal states of the circuit (represented collectively by the internal reference curve S0) are consistent under the external operating conditions v0 and t0, then the internal states of the circuit (represented collectively by the curve S1) are consistent for the external operating conditions v0 and t1 since the timing delays δt00 and δt01 are less than the predefined timing delay threshold δtth. Once it has been established that the curve S1 represents a properly internally functioning circuit, then curve S1 becomes the new reference curve to which the next timing comparisons are made.

Continuing with the embodiment of FIG. 3, the timing of the onset of the first and second collective internal states of curve S2 is compared to the timing of the onset of the first and second collective internal states of (reference) curve S1. According to the exemplary embodiment as illustrated, both δt10 and δt11 are less than the predefined threshold δtth. Consequently, the circuit is internally functional under the applied external boundary conditions v0 and t2. Curve S2 now becomes the new reference curve for comparison with the next collective internal states generated under a new temperature t3, where t3 is an incremental change of t2.

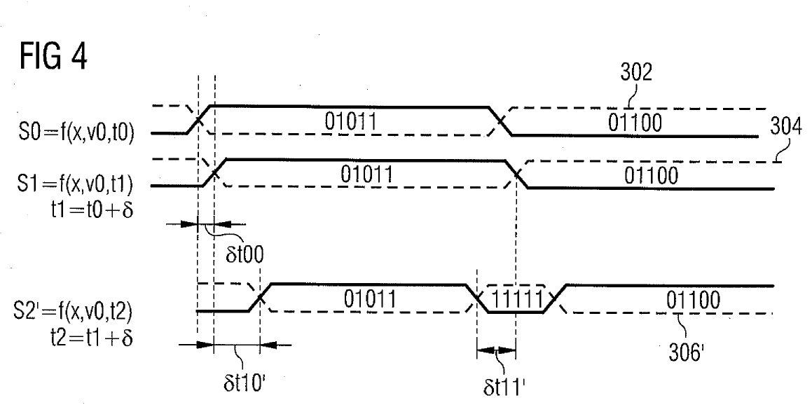

FIG. 4 is an illustration of collective internal states of an improperly functioning circuit, according to an embodiment. As illustrated, the collective internal states of the circuit are represented by a plurality of internal signals measured (or generated) at a plurality of internal circuit nodes as one or more external operating conditions are slowly varied.

The curve S0 and the curve S1 are identical to the same-referenced curves illustrated in FIG. 3. Thus, as described in conjunction with FIG. 3, the curve S1 is the reference curve for curve S2′. Curve S2′ represents collective internal states of the circuit for the given temperature t2, the given external voltage v0, the given chip input signal x, and clocked by a given clocking signal 306′. Curve S2′ has a first collective internal state represented by the states “0,” “1,” “0,” “1,” “1” of five internal signals measured and/or generated at five internal nodes, a transient collective internal state represented by the states “1,” “1,” “1,” “1,” “1” of five internal signals measured and/or generated at the same five internal nodes, and a second collective internal state represented by the states “0,” “1,” “1,” “0,” “0” of five internal signals measured and/or generated at the same five internal nodes. Similar to FIG. 3, the temperature t2=t1+δ.

In contrast to the embodiment as illustrated in FIG. 3, the onset of the first collective internal state of S2′ is delayed from the onset of the first collective internal state of S1 by δt10′, where δt10′ is greater than the predefined threshold δtth. Additionally, the onset of the transient collective internal state of S2′ is delayed from the onset of the second collective internal state of S1 by δt11,′ where δt11′ is greater than the predefined threshold δtth. That is, the transient collective internal state of curve S2′ is detected by the timing difference δt11′ between the onset of the second collective internal state of curve S1 and the onset of the transient collective internal state of curve S2′. Based upon a comparison of the timing differences δt10′ and δt11′ with the predefined timing difference threshold, the internal states of the circuit are determined to be inconsistent under the applied external boundary conditions v0 and t2. Although curve S2′ illustrates two timing differences greater than the predefined threshold, the scope of the invention contemplates detecting any number of timing differences that are greater than the predefined threshold.

Thus, even though the circuit as represented by the collective internal states illustrated in FIG. 4 may be observed to be functioning properly based upon its output signals, an analysis of the timing of the internal signals imply internal instabilities and inconsistencies for certain external boundary conditions. These internal instabilities may indicate that the circuit is operating at the outer envelope of its design specifications. The internal instabilities may indicate a design weakness for a circuit operating under the given external boundary conditions. If not detected, such a design weakness may eventually result in faulty output signals and catastrophic failure.

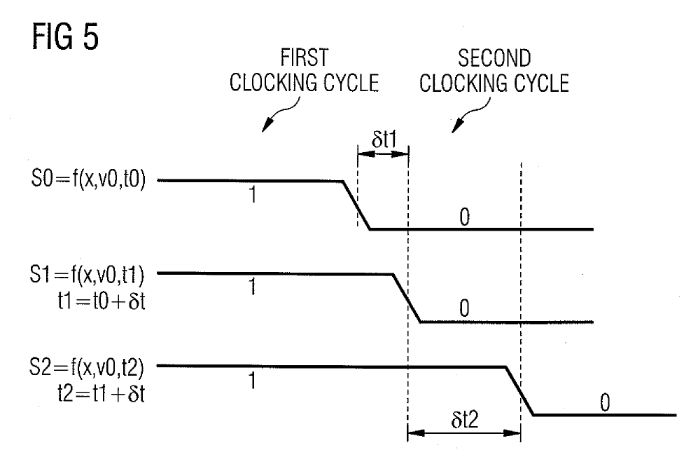

In an alternate embodiment, the curves S0, S1, S2 and S2′ may represent a state of a single internal node of a circuit (or chip). FIG. 5 is an exemplary illustration of an internal state representing an improperly functioning chip, according to one embodiment. As illustrated, an internal state of the chip is represented by an internal signal measured and/or generated at an internal chip node as one or more external operating conditions are slowly varied.

The curve S0 represents an internal state measured at internal node 1 for a given input signal x and external operating conditions v0 and t0, curve S1 represents an internal state measured at internal node 1 for the given input signal x and external operating conditions v0 and t1, and curve S2 represents an internal state measured at internal node 1 for the given input signal x and external operating conditions v0 and t2. For purposes of illustration, the internal state of the chip measured at node 1 for external operating conditions v0 and t0 is assumed to be correct, thus curve S0 is a reference curve from which the timing of the signals at node 1 represented by curve S1 (i.e., the curve representing the next incremental change in the external operating conditions) are compared.

As illustrated, the internal signal measured at node 1 during a first clocking cycle is 1, and the internal signal measured at node 1 during a second clocking cycle is 0. The timing difference of the change of state of the internal signal measured at node 1 between curves S0 (the reference curve) and S1 is δt1. In the embodiment as illustrated, δt1 is less than a predefined timing difference threshold. Since δt1 is less than the predefined timing difference threshold, the chip is operating with internal consistency with regard to internal node 1 given the input signal x and the external operating conditions v0 and t1.

Curve S1 now becomes the reference curve from which the timing of the signals at node 1 represented by curve S2 (i.e., the curve representing the next incremental change in the external operating conditions) are compared. The timing difference of the change of state of the internal signal measured at node 1 between curve S1 (the new reference curve) and curve S2 is δt2. However, since δ2 is greater than the predefined timing threshold, the chip is internally inconsistent with regard to the internal signal measured at node 1 for the given input signal x and the external operating conditions v0 and t2. Although curves S0, S1 and S2 each exhibit only two states (i.e., two clock cycles), the scope of the present invention covers any number of clock cycles and any number of timing difference comparisons between each of the curves.

In one embodiment, the external operating conditions are incrementally changed to generate a set of curves, where each curve represents the states of an internal signal at a given internal node for a given set of boundary conditions over a plurality of clock cycles. Similarly, other sets of curves are generated for different internal nodes, where each set of curves represents the internal states at a specific internal node as the external operating conditions are incrementally changed.

In one embodiment, if the timing difference at any internal node exceeds the timing difference threshold for a given set of external boundary conditions, then the chip is determined to be internally inconsistent for that given set of external boundary conditions. In another embodiment, the chip is not determined to be internally inconsistent for a given set of external boundary conditions unless a predefined minimum number of internal nodes are found to exceed the timing difference threshold.

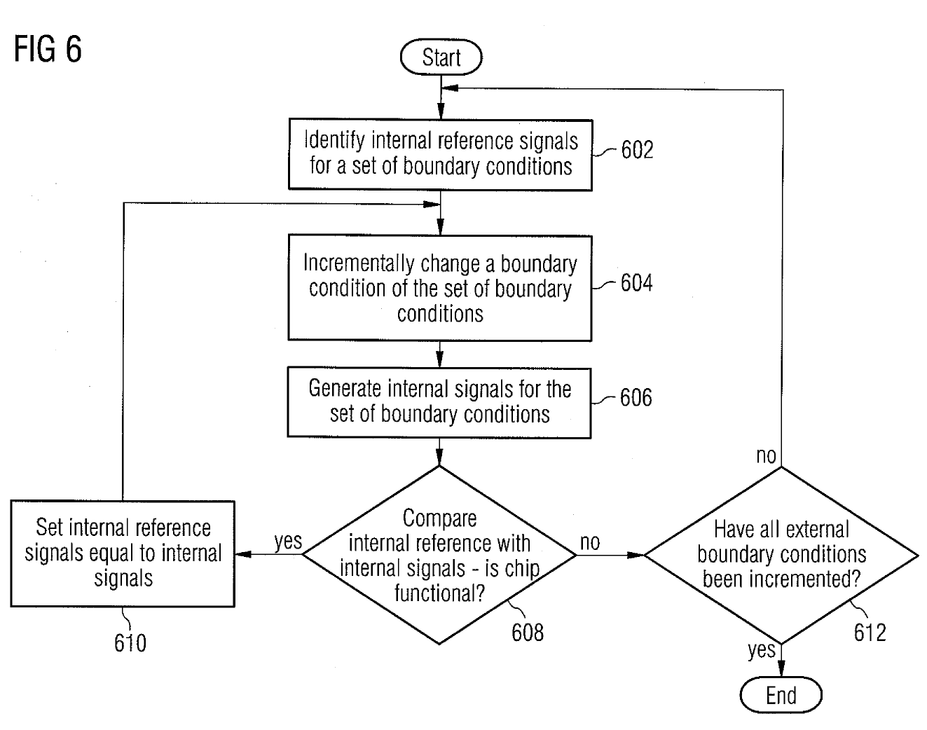

FIG. 6 is flowchart of one method for testing internal chip signals to determine chip functionality, according to one embodiment. The method may be described in conjunction with the embodiments illustrated in FIGS. 3-5. Additionally, the method may be implemented by any combination of hardware, firmware or software. One embodiment may be implemented by computer readable instructions embodied on a computer readable medium.

At 602, one or more internally consistent signals (associated with one or more internal chip nodes) generated by a given input signal x for an initial set of external operating conditions are identified as internal reference signals. An internal reference signal is an internal signal that changes state in a manner that is consistent with predicted internal chip performance for a given set of external operating conditions. For example, in one embodiment, a timing difference of a change of state of an internal signal measured at a given internal node may be determined by comparing the change of state of the internal signal to a change of state of the input signal x. If the timing difference falls within an acceptable predefined value, then the internal signal measured at the given node for the given set of external operating conditions is defined as an internal reference signal. The scope of the invention includes other methods known to one of skill in the art to determine an initial set of nodes that may serve as reference nodes (i.e., those nodes that have consistent internal signals with respect to a given input signal x and a given set of initial external operating conditions).

Next, at 604, one of the external operating conditions of the initial set of external operating conditions is incrementally changed to produce a new set of external operating conditions. An external operating condition (also referred to as an external boundary condition) may include, for example, ambient temperature, chip temperature, one or more externally applied voltages, frequency spectrum of the input signal x, clock duty-cycle, and commands/data set-up time. However, the scope of the present embodiments are not so limited, but includes all external operating conditions in all known combinations known to one of skill in the art.

At 606, one or more internal signals (associated with the one or more internal nodes) are generated for the given input signal x and the new set of external operating conditions. In one embodiment, the generated internal signals may be stored in memory of a computer system configured to implement the method. The one or more internal signals may be clocked over any number of clocking cycles, where the number of clocking cycles may be based upon clock-duty cycle and duration of the input signal x.

At 608, the one or more internal signals are compared with the one or more internal reference signals to determine whether the chip is functional under the new set of external operating conditions. In one embodiment, timing differences between the one or more internal reference signals and the one or more internal signals are determined. A timing difference may be made between an internal reference signal and an internal signal generated at the same internal node for each clock cycle. In another embodiment, the timing difference is the difference in time between when the internal signal switches state and the internal reference signal switches a state.

A chip is functional, for example, when its internal signals measured at the internal nodes have the correct magnitude and/or timing according to design specifications for a given chip input signal under a given set of external boundary conditions. In one embodiment, the chip is functional when each timing difference determined for each clock cycle of each internal signal is less than a predetermined timing difference threshold. The timing difference threshold may be an incrementally small time period as compared to the period of the clock cycle. In another embodiment, the chip is functional if the number of timing differences (for a given set of external boundary conditions) that exceed the timing difference threshold are less than a preset number. If the number of timing differences that exceed the timing difference threshold are greater (or equal) to the preset number, than the chip is (internally) inconsistent and nonfunctional.

If, at 608 the chip is found to be functional under the new set of external operating conditions, then at 610 the one or more internal signals (generated at 606) become the internal reference signals to which a next set of internal signals generated under a next incremented set of external operating conditions are compared. The method then continues at 604 in which one of the external operating conditions of the new set of external operating conditions is incrementally changed to produce the next incremented set of external operating conditions.

If, at 608, the chip is found to be nonfunctional under the new set of external operating conditions, then at 612 the method determines whether each of the one or more external operating conditions have been incremented over its full predetermined range. If each of the one or more external operating conditions have been incremented over its full predetermined range, then the method ends. If, however, each of the one or more external operating conditions have not been incremented over its full predetermined range, the method continues at 602, where one or more internal reference signals are identified for a set of boundary conditions for which internal signals have not yet been generated.

The scope of the present invention includes displaying the results of any combination of the illustrated embodiments as shmoo plots. According to one embodiment, a shmoo plot may be generated based upon a comparison of internal signals with internal reference signals for any number of incrementally-varying externally-applied operating conditions and for any magnitude of incremental change.

While the present embodiments have been described with reference to certain embodiments, it will be understood by those skilled in the art that various changes may be made and equivalents may be substituted without departing from the scope of the present invention. In addition, many modifications may be made to adapt a particular situation or material to the teachings without departing from its scope. Therefore, it is intended that the present invention not be limited to the particular embodiment disclosed, but that the present invention will include all embodiments falling within the scope of the appended claims.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for determining functionality of a circuit, comprising:
providing the circuit one or more internal nodes, the one or more internal nodes associated with one or more internal reference signals generated for a given input signal and an initial set of one or more external operating conditions;
changing at least one external operating condition of the initial set of external operating conditions to produce a next set of one or more external operating conditions;
generating one or more internal signals corresponding to the one or more internal nodes, the one or more internal signals generated for the given input signal and the next set of one or more external operating conditions; and
comparing the one or more internal signals with the one or more internal reference signals to determine whether the integrated circuit is functional under the next set of one or more external operating conditions.

2. The method of claim 1, wherein comparing the one or more internal signals with the one or more internal reference signals comprises determining timing differences between the one or more internal reference signals and the one or more internal signals, each timing difference determination made between an internal reference signal and an internal signal generated at a same internal node.

3. The method of claim 2, comprising basing each timing difference determination upon comparing a time at which the internal reference signal changes a state with a time at which the internal signal changes a state.

4. The method of claim 2, comprising wherein the circuit is not functional when at least one timing difference is greater than a timing difference threshold.

5. The method of claim 2, comprising wherein the circuit is not functional when the number of timing differences greater than a timing difference threshold exceeds a predefined minimum number.

6. The method of claim 2, comprising wherein the circuit is functional when each timing difference is less than a timing difference threshold.

7. The method of claim 1, comprising wherein the at least one external operating condition of the initial set of one or more operating conditions is temperature.

8. The method of claim 1, comprising wherein the at least one external operating condition of the initial set of one or more operating conditions is external voltage.

9. The method of claim 1, comprising providing the circuit integrated on a semiconductor chip.

10. The method of claim 1, further comprising:
if the circuit is functional under the next set of one or more external operating conditions,
setting the one or more internal reference signals equal to the one or more internal signals;
incrementally changing at least one external operating condition of the next set of external operating conditions to produce a further next set of one or more external operating conditions;
generating one or more internal signals for the given input signal and the further next set of one or more external operating conditions;
comparing the one or more internal signals generated for the given input signal and the further next set of external operating conditions with the one or more internal reference signals to determine whether the integrated circuit is functional under the further next set of one or more external operating conditions; and
if the integrated circuit is functional under the further next set of external operating conditions,
setting the next set of external operating conditions equal to the further next set of external operating conditions, and
repeating the steps of setting, incrementally changing, generating and comparing.

11. A method for determining functionality of a circuit, comprising:
generating one or more internal reference signals corresponding to one or more internal nodes of a circuit, the one or more internal reference signals corresponding to an input signal and an initial set of external operating conditions;
incrementally changing at least one external operating condition of the initial set of external operating conditions to produce a next set of one or more external operating conditions;
generating one or more internal signals corresponding to the one or more internal nodes, the one or more internal signals generated for the given input signal and the next set of one or more external operating conditions; and
comparing the one or more internal signals with the one or more internal reference signals to determine whether the integrated circuit is functional under the next set of one or more external operating conditions.

12. The method of claim 11, wherein comparing the one or more internal signals with the one or more internal reference signals comprises determining timing differences between the one or more internal reference signals and the one or more internal signals.

13. The method of claim 12, comprising making each timing difference determination between an internal reference signal and an internal signal generated at a same internal node.

14. The method of claim 12, comprising basing each timing difference determination upon comparing a time at which an internal reference signal changes a state with a time at which an internal signal changes a state.

15. The method of claim 12, comprising wherein the circuit is not functional when at least one timing difference is greater than a timing difference threshold.

16. The method of claim 11, comprising wherein the at least one external operating condition of the next set of one or more operating conditions is temperature.

17. The method of claim 11, comprising integrating the circuit on a semiconductor chip.

18. An electronic-readable medium having executable instructions to perform a method for determining functionality of a circuit, the circuit comprising one or more internal nodes, the one or more internal nodes associated with one or more internal reference signals generated for a given input signal and an initial set of one or more external operating conditions, comprising:
incrementally changing at least one external operating condition of the initial set of external operating conditions to produce a next set of one or more external operating conditions;
generating one or more internal signals corresponding to the one or more internal nodes, the one or more internal signals generated for the given input signal and the next set of one or more external operating conditions; and
comparing the one or more internal signals with the one or more internal reference signals to determine whether the integrated circuit is functional under the next set of one or more external operating conditions.

19. A system configured to determining functionality of a circuit, the circuit comprising one or more internal nodes, the one or more internal nodes associated with one or more internal reference signals generated for a given input signal and an initial set of one or more external operating conditions, the system comprising:
means for incrementally changing at least one external operating condition of the initial set of external operating conditions to produce a next set of one or more external operating conditions;
means for generating one or more internal signals corresponding to the one or more internal nodes, the one or more internal signals generated for the given input signal and the next set of one or more external operating conditions; and
means for comparing the one or more internal signals with the one or more internal reference signals to determine whether the integrated circuit is functional under the next set of one or more external operating conditions.

20. A system for determining functionality of a circuit, comprising:
the circuit including one or more internal nodes, the one or more internal nodes associated with one or more internal reference signals generated for a given input signal and an initial set of one or more external operating conditions;
wherein the system is configured to change at least one external operating condition of the initial set of external operating conditions to produce a next set of one or more external operating conditions, and
generate one or more internal signals corresponding to the one or more internal nodes, the one or more internal signals generated for the given input signal and the next set of one or more external operating conditions; and
a comparing circuit configured to compare the one or more internal signals with the one or more internal reference signals to determine whether the integrated circuit is functional under the next set of one or more external operating conditions.
